(19) United States
(12) Patent Application Publication
(10) Pub. No.: US 2026/0198069 A1
(43) Pub. Date: Jul. 9, 2026

(54) STACKED TRANSISTOR DEVICES AND METHODS OF FORMING THE SAME

(71) Applicant: Taiwan Semiconductor Manufacturing Co., Ltd., Hsinchu (TW)

(72) Inventors: Hsin Yang Hung, New Taipei (TW); Rui-Fu Chen, Hsinchu (TW); Shih-Jung Ho, Hsinchu (TW); Yu-Hsien Chiang, Hsinchu (TW); Che Chi Shih, Taoyuan (TW); Hung-Kun Lo, New Taipei (TW)

(21) Appl. No.: 19/209,200

(22) Filed: May 15, 2025

Related U.S. Application Data
(60) Provisional application No. 63/743,495, filed on Jan. 9, 2025.

(51) Int. Cl. H10D 84/01; H10D 84/85

(52) U.S. Cl. CPC H10D 84/0186; H10D 84/017; H10D 84/851; H10D 84/856

(57) ABSTRACT

A method includes forming a lower source/drain region adjacent first channel regions; forming an insulating layer over the lower source/drain region; forming a dummy source/drain region over the insulating layer, wherein the dummy source/drain region is adjacent second channel regions, wherein the second channel regions are over the first channel regions; after forming the dummy source/drain region, forming a gate structure over the first channel regions and the second channel regions; after forming the gate structure, removing the dummy source/drain region; forming an upper source/drain region adjacent the second channel regions; forming a silicide on the upper source/drain region; and forming a contact plug on the silicide, wherein an electrical conductivity of the silicide is between an electrical conductivity of the upper source/drain region and an electrical conductivity of the contact plug.

### PRIORITY CLAIM AND CROSS-REFERENCE

This application claims the benefit of the following provisionally filed U.S. Patent application: Application No. 63/743,495, filed on Jan. 9, 2025, which application is hereby incorporated herein by reference.

### BACKGROUND

Semiconductor devices are used in a variety of electronic applications such as personal computers, cell phones, digital cameras, and other electronic equipment. Semiconductor devices are typically fabricated by sequentially depositing insulating or dielectric layers, conductive layers, and semiconductor layers over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. As the minimum feature sizes are reduced, however, additional problems arise and should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A, 1B, 2A, 2B, 3A, 3B, 4A, 4B, 5A, 5B, 6A, 6B, 7A, 7B, 8A, 8B, 9A, 9B, 10A, 10B, 11A, 11B, 12A, and 12B are views of intermediate stages in the formation of contact plugs of a stacking transistor structure, in accordance with some embodiments.

FIGS. 13A, 13B, 14A, and 14B are views of intermediate stages in the formation of contact plugs of a stacking transistor structure, in accordance with some embodiments.

FIGS. 15A, 15B, 16A, and 16B are views of intermediate stages in the formation of contact plugs of a stacking transistor structure, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Various representative embodiments are described with respect to contact plugs within stacking transistor structures. Complementary Field-Effect Transistors (CFETs), silicide regions, contact plugs, and the method of forming the same are provided. In accordance with some embodiments of the present disclosure, dummy source/drain regions are replaced with upper source/drain regions after replacement gate stacks are formed. This can allow the upper source/drain regions to be highly doped without increasing thermal dopant diffusion into the channel regions. Forming silicide regions on the more highly doped upper source/drain regions can reduce resistance and improve device performance.

It is appreciated that while the discussion herein in presented in the context of the formation of stacking transistors including Gate-All-Around (GAA) transistors (such as nanostructure-FETs), the concept of the present disclosure can also be applied to the formation of other types of transistors such as planar transistors, Fin Field-Effect Transistors (FinFETs), and the like. Throughout the description, the terms “FET” and “transistor” are used interchangeably.

Embodiments discussed herein are to provide examples to enable making or using the subject matter of this disclosure, and a person having ordinary skill in the art will readily understand modifications that can be made while remaining within contemplated scopes of different embodiments. Throughout the various views and illustrative embodiments, like reference numbers are used to designate like elements. Although method embodiments may be discussed as being performed in a particular order, other method embodiments may be performed in any logical order.

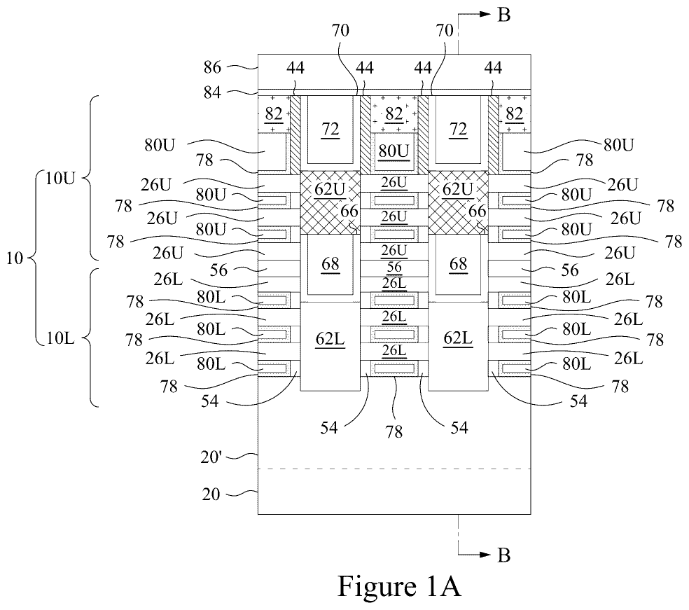

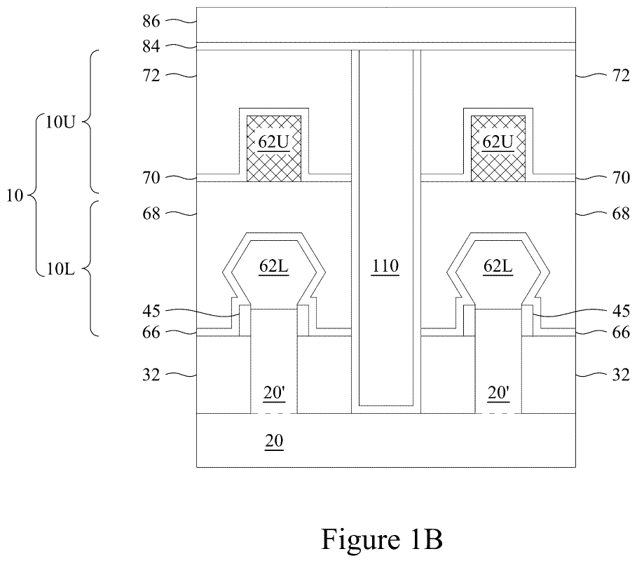

FIGS. 1A-1B through 12A-12B illustrate cross-sectional views of intermediate stages in the formation of a stacking transistor structure, in accordance with some embodiments. The stacking transistor structure may be a Complementary Field-Effect Transistor (CFET) structure, in some cases. FIGS. 1A-1B illustrate an intermediate stage in the formation of a stacking transistor 10, in accordance with some embodiments. The stacking transistor 10 includes multiple vertically stacked FETs. For example, a stacking transistor may include a lower nanostructure-FET 10L of a first device type (e.g., n-type/p-type) and an upper nanostructure-FET 10U of a second device type (e.g., p-type/n-type). When the stacking transistor is a CFET, the second device type of the upper nanostructure-FET 10U is opposite to the first device type of the lower nanostructure-FET 10L. For example, in some embodiments, the lower nanostructure-FET 10L is a p-type transistor and the upper nanostructure-FET 10N is a n-type transistor. The nanostructure-FETs 10U and 10L include semiconductor nanostructures 26 (including lower semiconductor nanostructures 26L and upper semiconductor nanostructures 26U), in which the semiconductor nanostructures 26 act as the channel regions for the nanostructure-FETs. The lower semiconductor nanostructures 26L are for the lower nanostructure-FET 10L, and the upper semiconductor nanostructures 26U are for the upper nanostructure-FET 10U. In other embodiments, the stacking transistors may be applied to other types of transistors (e.g., FinFETs, or the like) as well.

In some embodiments, the stacking transistor 10 is formed on a wafer, which may include a substrate 20. The substrate 20 may be a semiconductor substrate, such as a bulk semiconductor, a semiconductor-on-insulator (SOI) substrate, or the like, which may be doped (e.g., with a p-type or an n-type dopant) or undoped. A SOI substrate may include a layer of a semiconductor material formed on an insulator layer. The insulator layer may be, for example, a buried oxide (BOX) layer, a silicon oxide layer, or the like. The insulator layer is provided on a substrate, such as a silicon or glass substrate. Other substrates, such as a multilayered or gradient substrate may also be used. In some embodiments, the semiconductor material of the substrate 20 may include silicon, germanium, carbon-doped silicon, a III-V compound semiconductor, or the like, or combinations thereof.

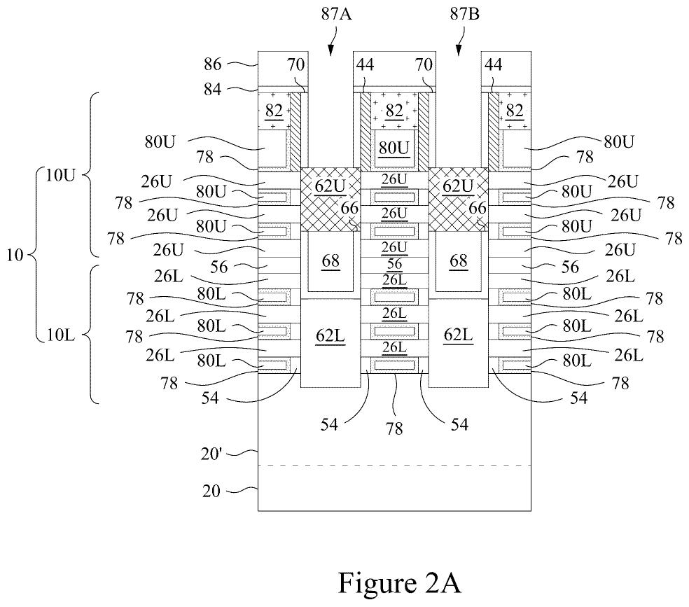

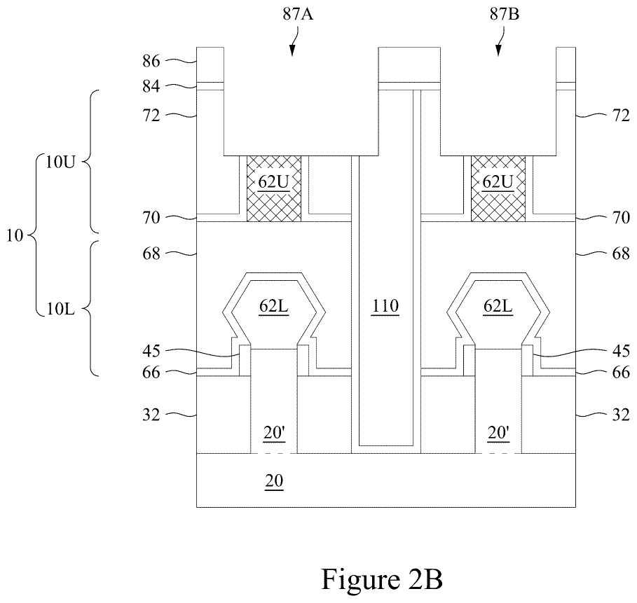

Gate dielectrics 78 encircle the respective semiconductor nanostructures 26. Gate electrodes 80 (including a lower gate electrode 80L and an upper gate electrode 80U) are over the gate dielectrics 78. The gate dielectrics 78 and gate electrodes 80 form “gate stacks” or “gate structures” between the semiconductor nanostructures 26. Upper gate stacks include gate dielectrics 78 and upper gate electrodes 80U. Lower gate stacks include gate dielectrics 78 and lower gate electrodes 80L. Dielectric hard masks 82 are formed over the gate stacks. Accordingly, the subsequent process steps (e.g., FIGS. 2A-12B) described herein are performed after formation of the replacement gate stacks. In some cases, the subsequent process steps described herein may be performed during a middle end of line (MEOL) stage of processing.

Dielectric isolation layers 56 are formed to isolate the gate stacks of the upper FETs 10U from the gate stacks of the lower FETs 10L. The semiconductor layers adjacently above and below the dielectric isolation layers 56 may be dummy semiconductor layers (e.g., dummy nanostructures), in some embodiments.

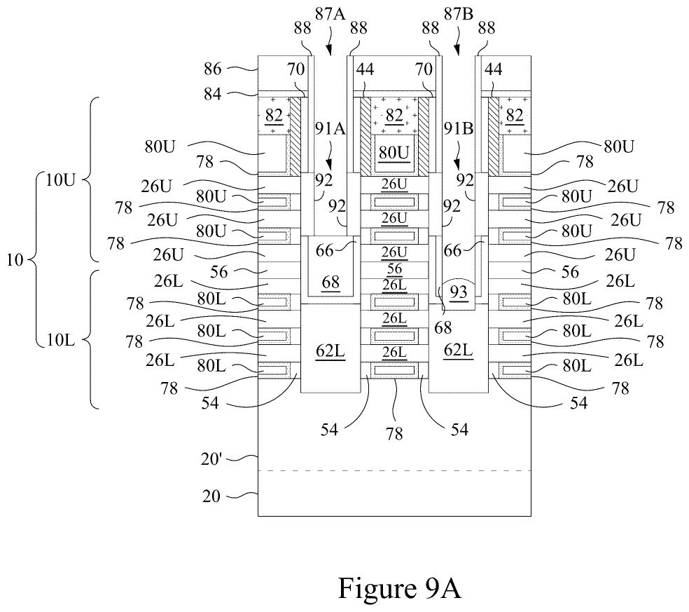

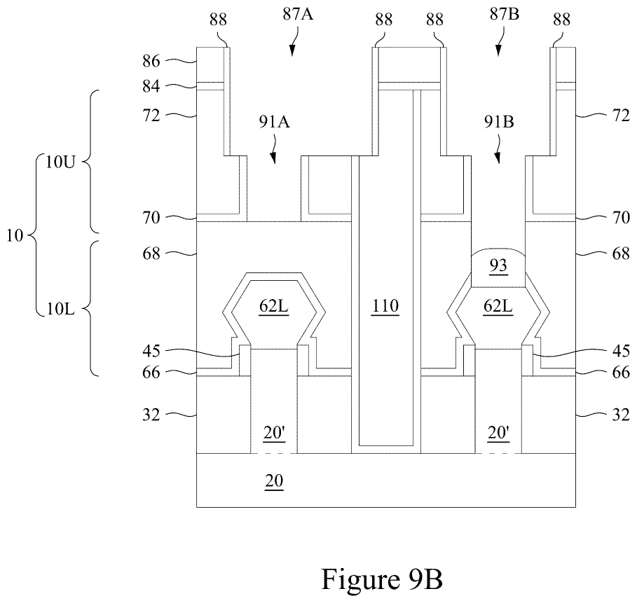

Source/drain regions 62 are disposed on opposing sides of the gate stacks (e.g., the gate dielectrics 78 and the respective gate electrodes 80). A source/drain region 62 may refer to a source or a drain, individually or collectively dependent upon the context. In some embodiments, at the process stage illustrated in FIGS. 1A-1B, the source/drain regions 62 include lower source/drain regions 62L and upper dummy regions 62U, described in greater detail below. The upper dummy regions 62U are subsequently replaced with upper source/drain regions 92 (see FIGS. 9A-9B). Isolation features (not shown) may be formed to separate desired ones of the source/drain regions 62 and/or desired ones of the gate electrodes 80.

Inner spacers 54, which are dielectric spacers, are formed on the opposing sides of the portions of gate stacks, which portions are between semiconductor nanostructures 26. Inner spacers 54 electrically insulate the lower source/drain regions 62L and the upper source/drain regions 92 from the corresponding parts of gate stacks to prevent and reduce leakage. Gate spacers 44 are formed over the multilayer stacks and on the sidewalls of the gate stacks. The gate spacers 44 may be formed by conformally forming one or more dielectric layers and subsequently etching the dielectric layers anisotropically. The applicable dielectric materials may include silicon oxide, silicon nitride, silicon oxynitride, silicon oxycarbonitride, or the like, which may be formed by a deposition process such as Chemical Vapor Deposition (CVD), Atomic Layer Deposition (ALD), or the like.

The source/drain regions 62L and 62U are formed laterally between the multilayer stacks that comprise the channel regions (e.g., the semiconductor nanostructures 26) and the gate stacks (e.g., the gate dielectrics 78 and the gate electrodes 80). Lower source/drain regions 62L are formed over and contacting a substrate, which includes substrate 20. The lower source/drain regions 62L are further in contact with the lower semiconductor nanostructures 26L and are not in contact with the upper semiconductor nanostructures 26U.

The lower source/drain regions 62L are epitaxially grown, and have a conductivity type that is suitable for the device type (p-type or n-type) of the lower nanostructure-FETs. When lower source/drain regions 62L are n-type source/drain regions, the respective material may include silicon or carbon-doped silicon, which is doped with an n-type dopant such as phosphorous, arsenic, or the like. When lower source/drain regions 62L are p-type source/drain regions, the respective material may include silicon or silicon germanium, which is doped with a p-type dopant such as boron, indium, or the like. The lower source/drain regions 62L may be in-situ doped, and may be, or may not be, implanted with the corresponding p-type or n-type dopants

A first contact etch stop layer (CESL) 66 and a first inter-layer dielectric (ILD) 68 are formed over the lower source/drain regions 62L. The first ILD may be a dielectric layer, an insulating layer, or the like. The applicable dielectric material of the first ILD 68 may include phospho-silicate glass (PSG), boro-silicate glass (BSG), boron-doped phospho-silicate glass (BPSG), undoped silicate glass (USG), silicon oxide, or the like. The first CESL 66 may be formed of a dielectric material having a high etching selectivity from the etching of the first ILD 68. For example, the first CESL 66 may comprise silicon nitride, silicon oxide, silicon oxynitride, or the like, which may be formed by any suitable deposition process, such as CVD, ALD, or the like.

Upper dummy regions 62U are formed overlapping the first CESL 66 and the first ILD 68, and overlapping the lower source/drain regions 62L. In some embodiments, the material of the upper dummy regions 62U has a high etching selectivity to the material of the lower source/drain regions 62L and/or the semiconductor nanostructures 26. In this manner, the upper dummy regions 62U may subsequently be removed with little or no etching of the lower source/drain regions 62L and/or the semiconductor nanostructures 26. For example, in some embodiments, the upper dummy regions 62U may be formed of germanium or silicon germanium (SiGe), and the lower source/drain regions 62L may be formed of silicon. The upper dummy regions 62U may be crystalline, amorphous, or polycrystalline, and may be doped or undoped. The upper dummy regions 62U may be formed using an epitaxial process.

A second CESL 70 and a second ILD 72 are formed over the upper dummy regions 62U. The materials may be similar to, and may be the same as or different from, the materials and the formation methods of the first CESL 66 and first ILD 68, respectively, and are not discussed in detail herein. An etch stop layer (ESL) 84 is formed over the second CESL 70, the second ILD 72, the dielectric hard masks 82, and the gate spacers 44. The etch stop layer 84 may comprise aluminum nitride, aluminum oxide, silicon oxycarbide, the like, or multilayers thereof. A dielectric layer 86 is formed over the etch stop layer 84. The dielectric layer 86 may comprise silicon oxide, silicon nitride, silicon oxynitride, silicon carbide, or the like. Other materials are possible.

FIG. 1B illustrates a cross-sectional view of the structure as shown in FIG. 1A. The illustrated cross-section may be similar to the cross-section B-B′ indicated in FIG. 1A. Dielectric isolation regions 32, also sometimes referred to as Shallow Trench Isolation (STI) regions 32, are formed over the substrate 20. Semiconductor strips 20′ (also refer to FIG. 1A) are formed between the STI regions 32. The semiconductor strips 20′ may be considered semiconductor fins, in some cases. Fin spacers 45 may be formed on the sidewalls of the top portions of the semiconductor strips 20′. The lower source/drain regions 62L, the first CESL 66, the first ILD 68, the upper dummy regions 62U, the second CESL 70, and the second ILD 72 are also illustrated in FIG. 1B.

In some embodiments, a dielectric region 110 is formed between neighboring lower source/drain regions 62L and/or neighboring upper dummy regions 62U. The dielectric region 110 may extend through the second ILD 72, the second CESL 70, the first ILD 68, the first CESL 66, and the isolation region 32. In other embodiments, the dielectric region 110 may extend partially through the isolation region 32 or through the isolation region 32 and into the substrate 20. In some embodiments, the dielectric region 110 may be used as a cut metal gate region that separates a long gate stack into shorter portions. In some embodiments, a conductive feature (not separately illustrated) is formed within the dielectric region 110. The conductive feature may be, for example, a contact plug, a vertical local interconnect (VLI), a via, or the like. The conductive feature may be used to electrically connect features on opposite sides of the structure, in some cases.

In FIGS. 2A-2B, openings 87A-B are formed that expose the upper dummy regions 62U, in accordance with some embodiments. The openings 87A-B extend through the dielectric layer 86, the etch stop layer 84, the second ILD 72, and the second CESL 70. One or more of the openings 87A-B may extend into the dielectric region 110, as shown in FIG. 2B. Forming the openings 87A-B at least partially removes portions of the second CESL 70 over the upper dummy regions 62U, and may remove upper portions of the upper dummy regions 62U. In the embodiment shown in FIGS. 2A-2B, the opening 87A exposes one upper dummy region 62U, and the opening 87B exposes another upper dummy region 62U. As shown in FIG. 2B, a width of the openings 87A-B may be greater than a width of the upper dummy regions 62U.

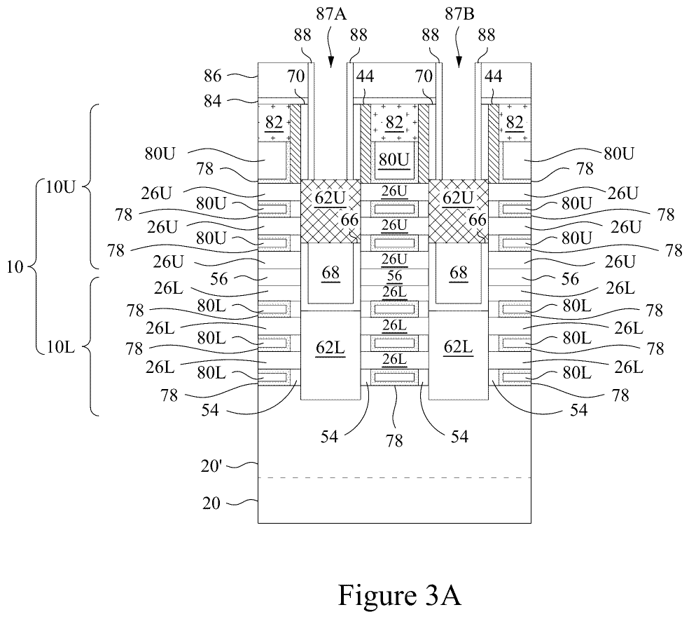

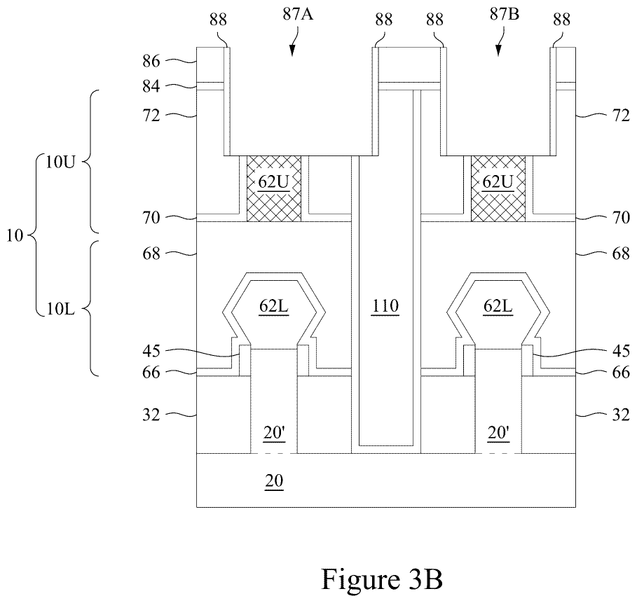

In FIGS. 3A-3B, dielectric liners 88 are formed on sidewalls of the openings 87A-B, in accordance with some embodiments. The dielectric liners 88 may be formed, for example, by depositing a conformal dielectric layer in the openings 87A-B using a conformal deposition process, and then performing an anisotropic etching process to remove the horizontal portions of the conformal dielectric layer. The remaining vertical portions of the conformal dielectric layer form the dielectric liners 88. The dielectric liners 88 may comprise one or more dielectric materials such as silicon nitride, silicon oxynitride, silicon carbide, silicon carbonitride, the like, or a combination thereof. The upper dummy regions 62U remain exposed after forming the dielectric liners 88.

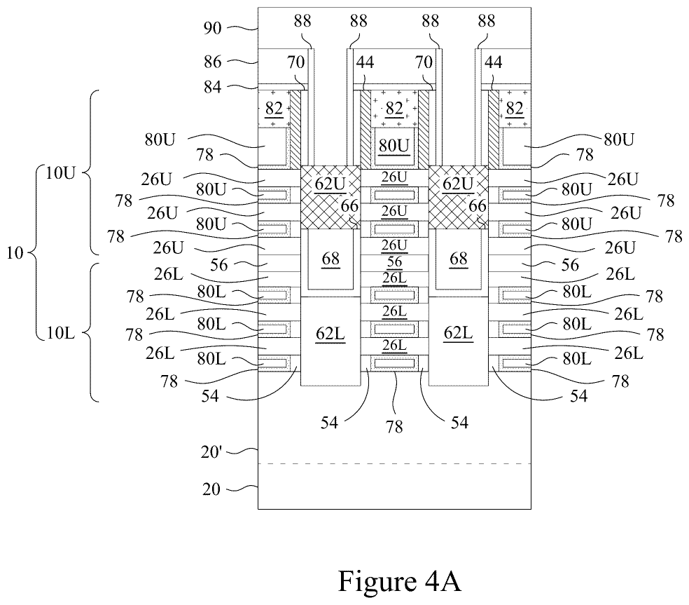

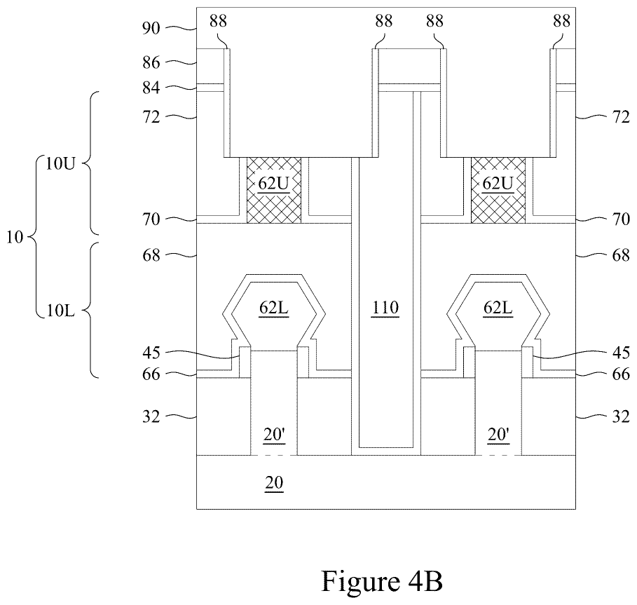

In FIGS. 4A-4B, a mask material 90 is formed over the dielectric layer 86 and within the openings 87A-B, in accordance with some embodiments. The mask material 90 may fill the openings 87A-B, as shown in FIGS. 4A-4B. The mask material 90 may comprise, for example, a photoresist, a polymer, a bottom anti-reflection coating (BARC), or the like. The mask material 90 may be part of a multi-layer photoresist structure (not illustrated), in some embodiments.

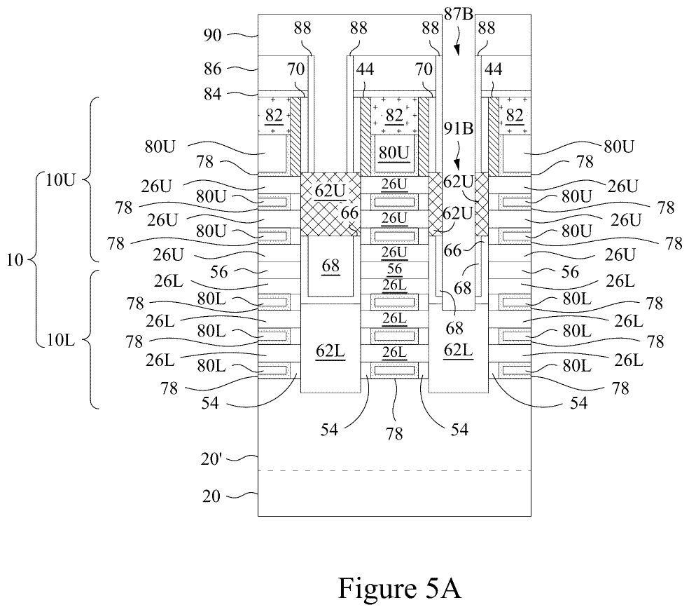

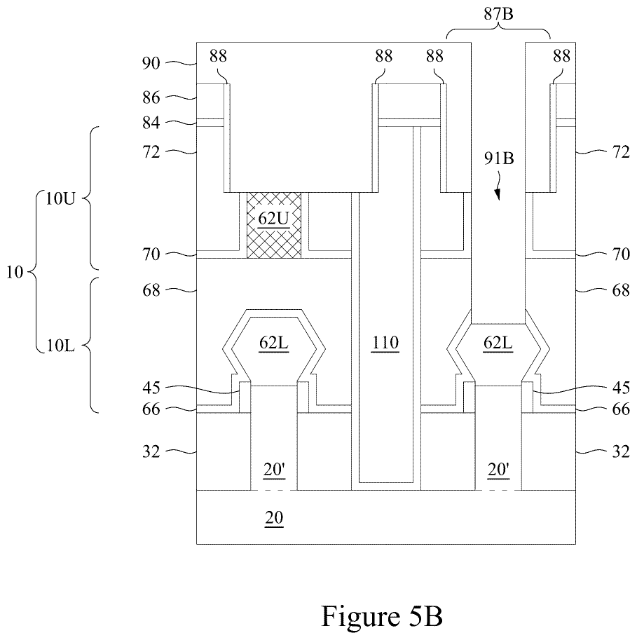

In FIGS. 5A-5B, an opening 91B is formed that extends the opening 87B to a lower source/drain region 62L, in accordance with some embodiments. The opening 91B may be formed, for example, by patterning the mask material 90 and then using the patterned mask material 90 as an etch mask. The mask material 90 may be patterned using suitable photolithographic techniques, and may expose the underlying upper dummy region 62U. Then, one or more etching processes may be performed to extend the pattern of the mask material 90 through the upper dummy region 62U, the first ILD 68, and the first CESL 66, forming the opening 91B. The opening 91B exposes the underlying lower source/drain region 62L, and the etching processes may remove upper portions of the lower source/drain region 62L. As shown in FIG. 5B, a width of the opening 91B may be smaller than a width of the opening 87B. In some cases, the dielectric liners 88 and/or the second CESL 70 may act as etch stop layers that stop or slow lateral etching. In this manner, the etching of the opening 91B may be considered a “self-aligned” process, in some cases. In some embodiments, some portions of the upper dummy region 62L remain on the upper semiconductor nanostructures 26U after forming the opening 91B.

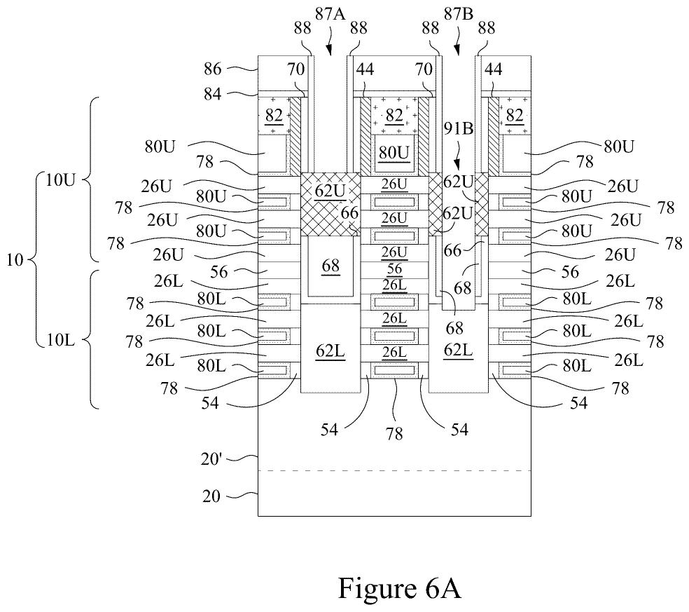

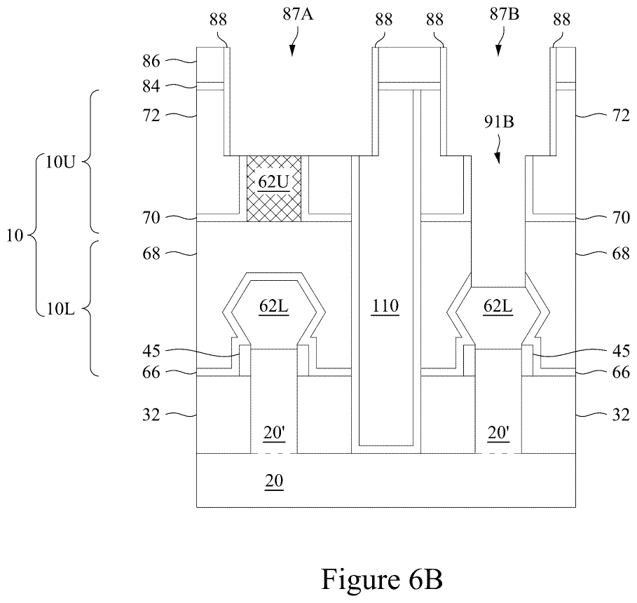

In FIGS. 6A-6B, the mask material 90 is removed, in accordance with some embodiments. The mask material 90 may be removed using a suitable technique, such as an etching process or an ashing process. After removing the mask material 90, a top surface of an upper dummy region 62U is exposed by the opening 87A, sidewalls of an upper dummy region 62U are exposed by the opening 91B, and a top surface of a lower source/drain region 62L is exposed by the opening 91B. As shown in FIG. 6B, in some embodiments, the opening 87B is wider than the opening 91B. In this manner, the combination of the opening 87B and the opening 91B can be considered a single opening that is wider near the top and narrower near the bottom. The openings 87A, 87B, and 91B are shown as having straight and vertical sidewalls, but may have angled or tapered sidewalls in some cases.

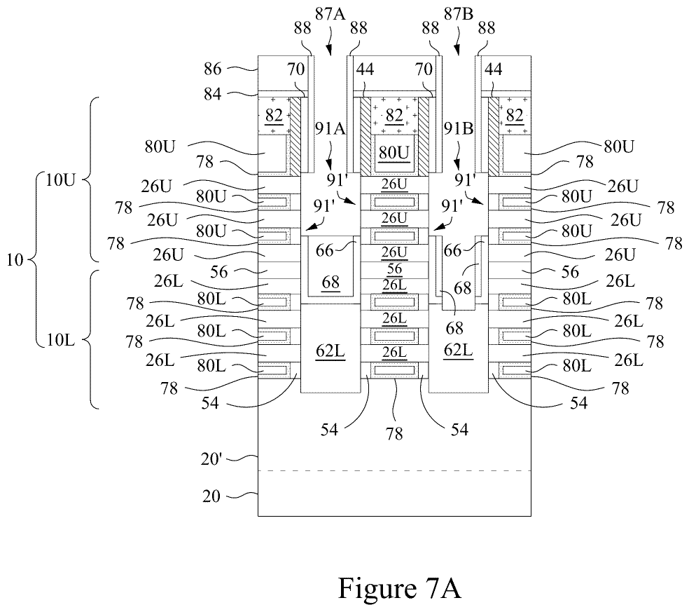

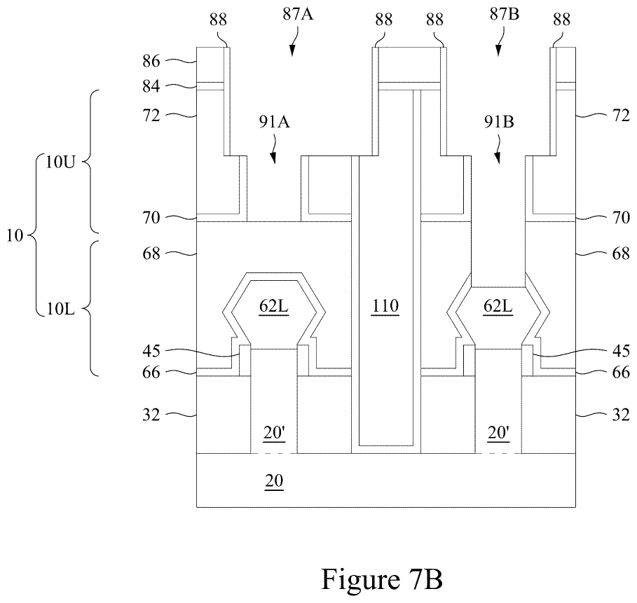

In FIGS. 7A-7B, the upper dummy regions 62U are removed, in accordance with some embodiments. The upper dummy regions 62U may be removed using an etching process that is selective to the material of the upper dummy regions 62U and does not substantially etch the upper semiconductor nanostructures 26U and the lower source/drain regions 62L. For example, the etching process may etch the material of the upper dummy regions 62U at a faster rate than the material of the lower source/drain regions 62L. After removing the upper dummy regions 62U, sidewalls of the upper semiconductor nanostructures 26U are exposed. Removing the upper dummy region 62U underneath the opening 87A forms an opening 91A that extends the opening 87A to the first ILD 68. As shown in FIG. 7B, in some embodiments, a width of the opening 87A may be greater than a width of the opening 91A. Removing the upper dummy regions 62U may form sidewall recesses 91′ in the openings 91A-B, within which one or more upper semiconductor nanostructures 26U and one or more inner spacers 54 are exposed.

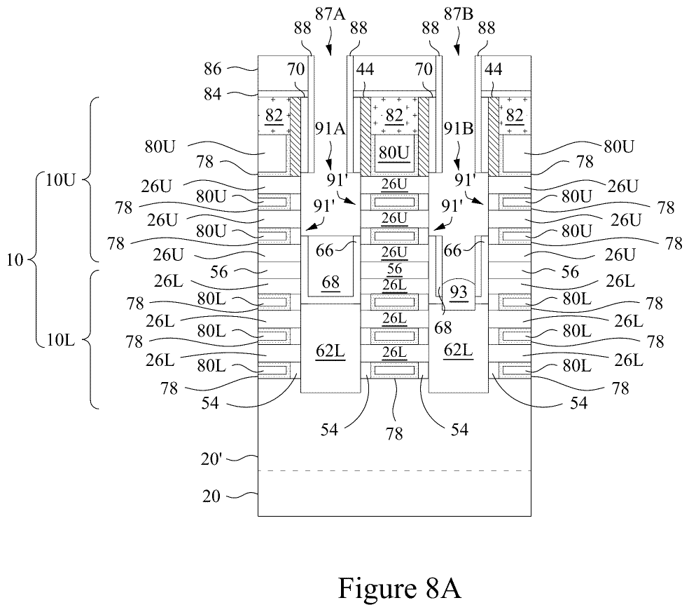

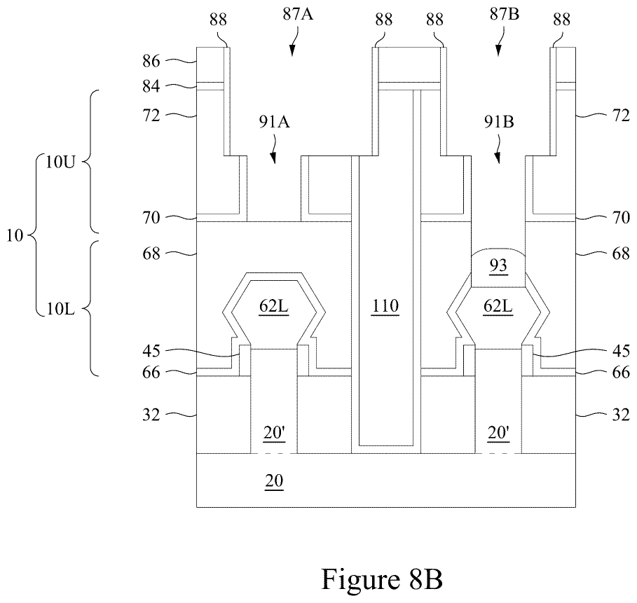

In FIGS. 8A-8B, a mask 93 is deposited to cover the lower source/drain region 62L exposed by the opening 91B. The mask 93 may be, for example, a photoresist, polymer, BARC, or the like. In some embodiments, the mask 93 comprises a dielectric material such as silicon oxide, silicon nitride, or the like. In some embodiments, the mask 93 comprises a self-assembled material (e.g., a self-assembled monolayers (SAM)) or the like. The mask 93 may be deposited using suitable deposition techniques, and then may be patterned or etched such that the mask 93 covers the lower source/drain region 62L but leaves sidewalls of the upper semiconductor nanostructures 26U exposed by the openings 91A-B. Other materials or techniques for forming the mask 93 are possible.

In FIGS. 9A-9B, upper source/drain regions 92 are formed on the upper semiconductor nanostructures 26U, in accordance with some embodiments. The upper source/drain regions 92 may extend continuously over the sidewalls of one or more upper semiconductor nanostructures 26U and over the sidewalls of one or more inner spacers 54, in some embodiments. The upper source/drain regions 92 may extend continuously over the sidewalls of multiple upper semiconductor nanostructures 26U, in some embodiments.

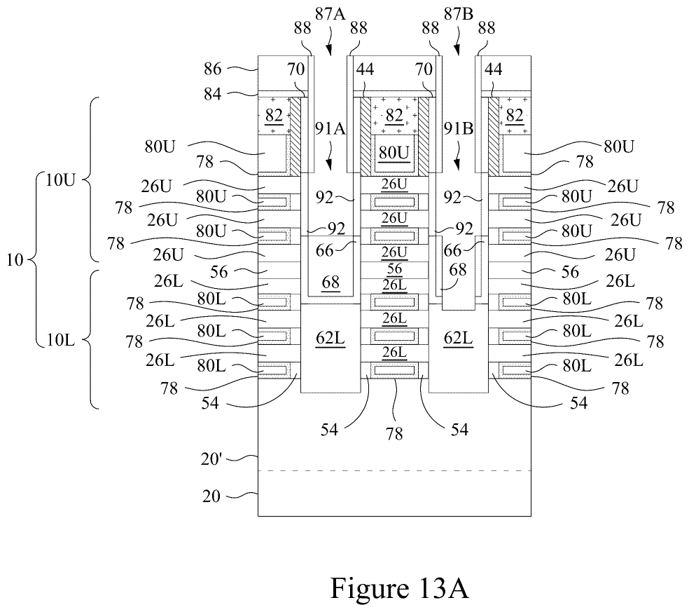

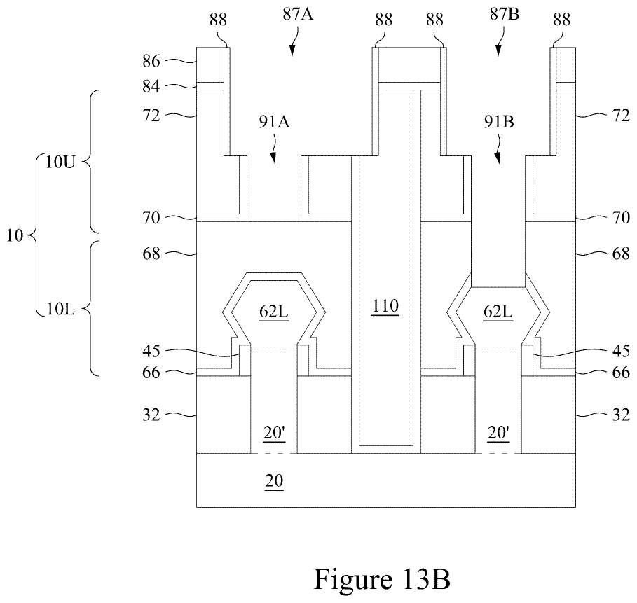

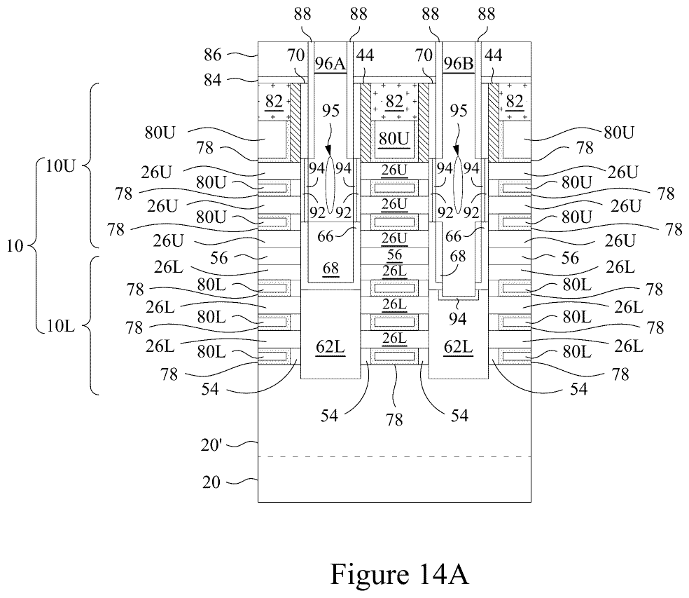

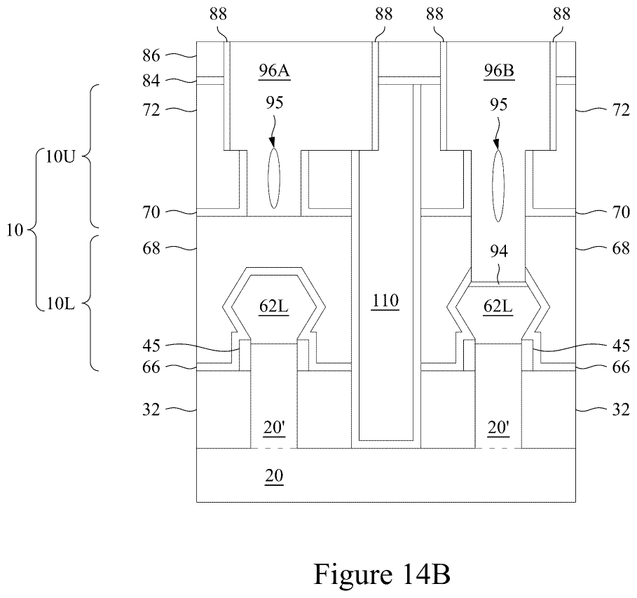

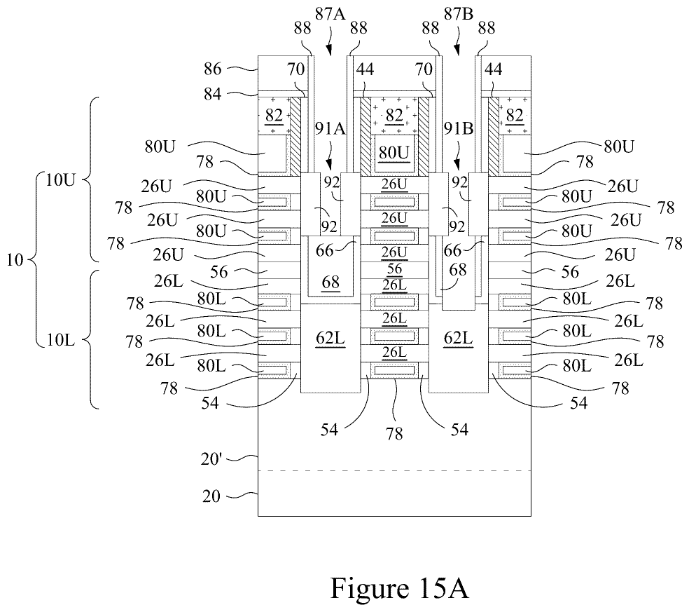

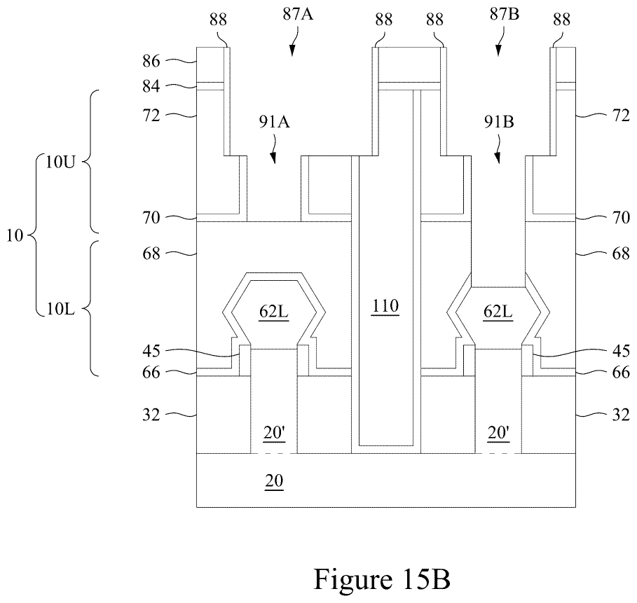

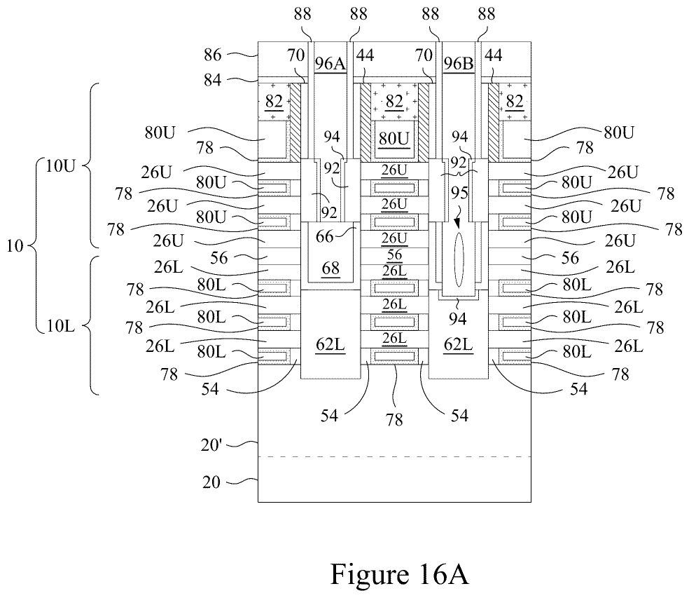

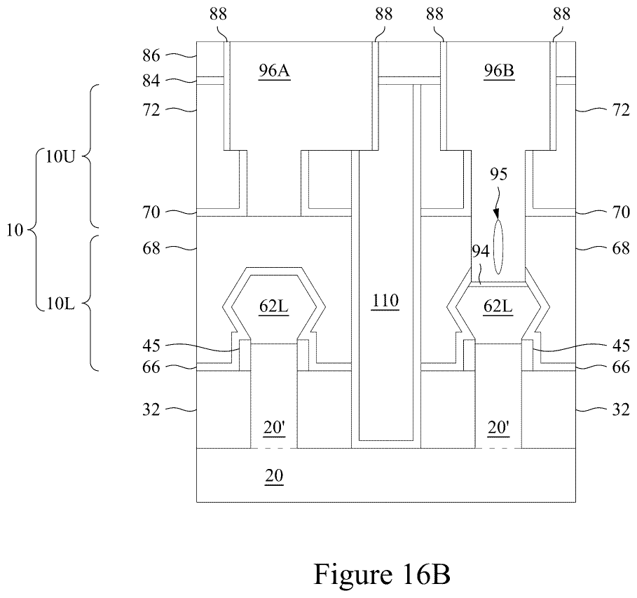

The upper source/drain regions 92 may partially or fully fill the sidewall recesses 91′ formed by the removal of the upper dummy regions 62U. In some embodiments, the upper source/drain regions 92 may have a thickness (e.g., a width) in the range of about 1 nm to about 1 μm, though other thicknesses are possible. In some embodiments, a thickness of the upper source/drain regions 92 may be similar to a depth of the sidewall recesses 91′. In other words, sidewalls of the upper source/drain regions 92 may be approximately flush with sidewalls of the dielectric liners 88 and/or with sidewalls of the first ILD 68 exposed by the opening 91B. In other embodiments, the upper source/drain regions 92 may partially fill the sidewall recesses 91′ such that sidewalls of the upper source/drain regions 92 may be recessed from sidewalls of the dielectric liners 88 and/or sidewalls of the first ILD 68 exposed by the opening 91B (see FIGS. 13A-14B). In other embodiments, the upper source/drain regions 92 may overfill the sidewall recesses 91′ such that sidewalls of the upper source/drain regions 92 may protrude from sidewalls of the dielectric liners 88 and/or sidewalls of the first ILD 68 exposed by the opening 91B (see FIGS. 15A-16B). Because the upper source/drain regions 92 do not fill or extend fully across the openings 91A-B, in some cases the upper source/drain regions 92 may be considered layers, such as epitaxial layers, source/drain layers, or the like.

The materials of upper source/drain regions 92 may be selected from the same candidate group of materials for forming lower source/drain regions 62L, depending on the desired conductivity type of upper source/drain regions 92. The conductivity type of the upper source/drain regions 92 may be opposite the conductivity type of the lower source/drain regions 62L. Alternatively stated, the upper source/drain regions 92 may be oppositely doped than the lower source/drain regions 62L. When the upper source/drain regions 92 are n-type source/drain regions, the respective material may include silicon or carbon-doped silicon, which is doped with an n-type dopant such as phosphorus, arsenic, or the like. In some embodiments, the upper source/drain regions 92 have a high doping concentration, such as a doping concentration in the range of about 1E21 cm⁻³ to about 1E22 cm⁻³, though other doping concentrations are possible. Each upper source/drain region 92 may be uniformly doped and have a uniform (e.g., homogeneous) composition (within process variations), in some embodiments. In some embodiments, the upper source/drain regions 92 may be silicon that is highly doped with phosphorus (e.g., SiP) and is free of arsenic. Other materials, dopants, or combinations thereof are possible.

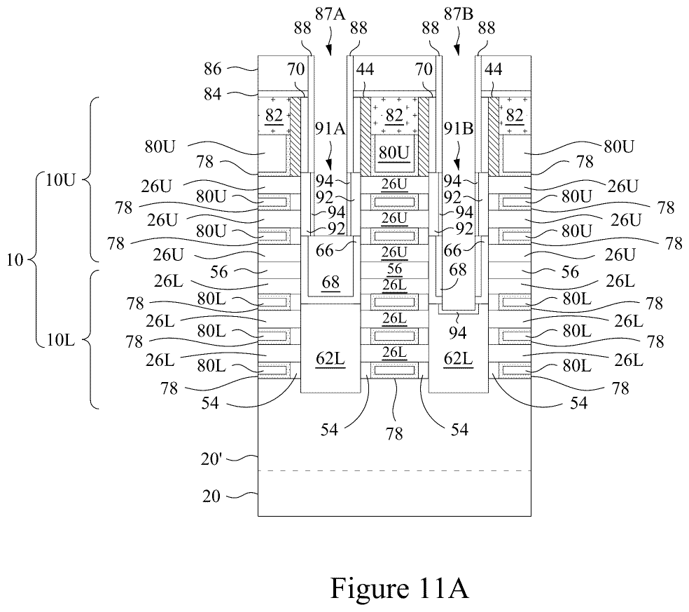

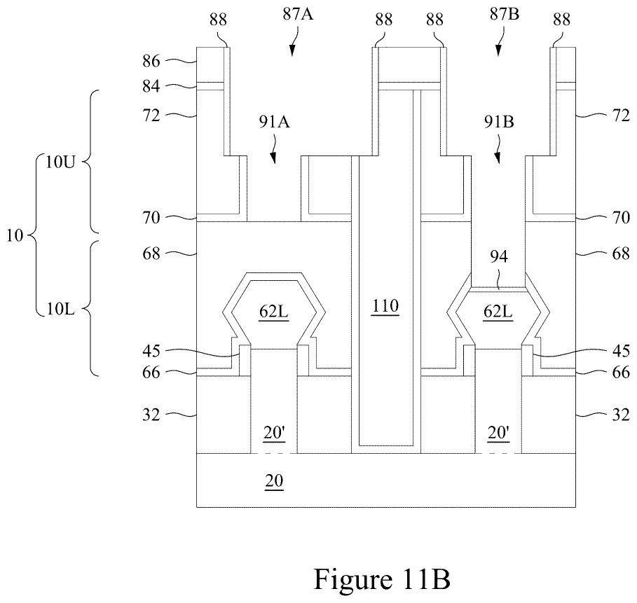

Forming the upper source/drain regions 92 after forming the replacement gate stacks, as described herein, can allow for the upper source/drain regions 92 to be more highly doped. For example, forming the upper source/drain regions 92 after forming the replacement gate stacks can reduce dopant diffusion into the upper semiconductor nanostructures 26U that can decrease device performance. In some embodiments, this can eliminate the need for a more resistive lower-doped epitaxial region that acts as a diffusion barrier. In this manner, the techniques described herein can allow for improved contact between the upper source/drain regions 92 and the upper semiconductor nanostructures 26U. In some cases, upper source/drain regions 92 with a higher doping concentration can have reduced contact resistance between the upper source/drain regions 92 and an overlying silicide region 94 (see FIGS. 11A-11B).

The upper source/drain regions 92 are formed using an epitaxial process. The material of the upper source/drain regions 92 may be grown from the exposed sidewalls of the upper semiconductor nanostructures 26U. Because the lower source/drain region 62L is covered by the mask 93, no material is formed on the lower source/drain region 62L by the epitaxial process. In some embodiments, the epitaxial material of the upper source/drain regions 92 is grown as continuous layers that extend over the exposed upper semiconductor nanostructures 26U. In other embodiments, the epitaxial material is grown separately on each exposed sidewall of the upper semiconductor nanostructures 26U, and neighboring regions of epitaxial material merge to form upper source/drain regions 92. In some embodiments, the process temperature for forming the upper source/drain regions 92 may be a relatively low temperature. For example, the epitaxial process that forms the upper source/drain regions 92 may include a process temperature that is lower than process temperature used to form the lower source/drain regions 62L and/or the process temperature used to form the upper dummy regions 62U. In some cases, a lower process temperature may reduce thermal damage, reduce undesired dopant diffusion, or improve device reliability.

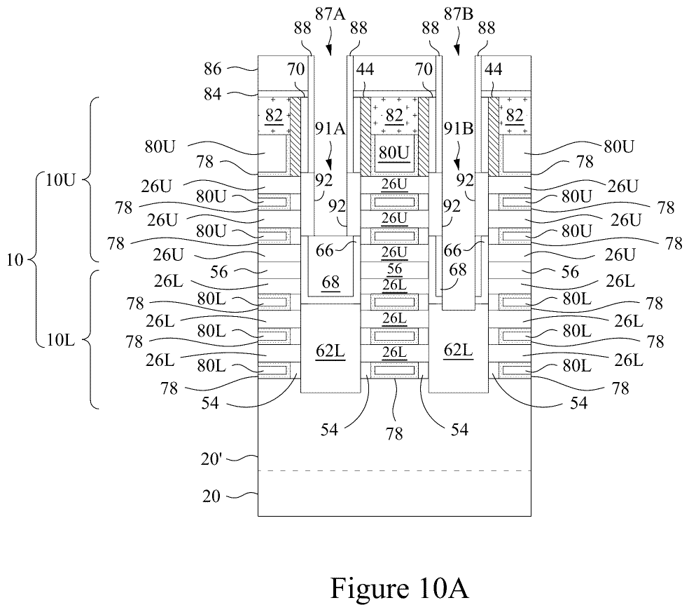

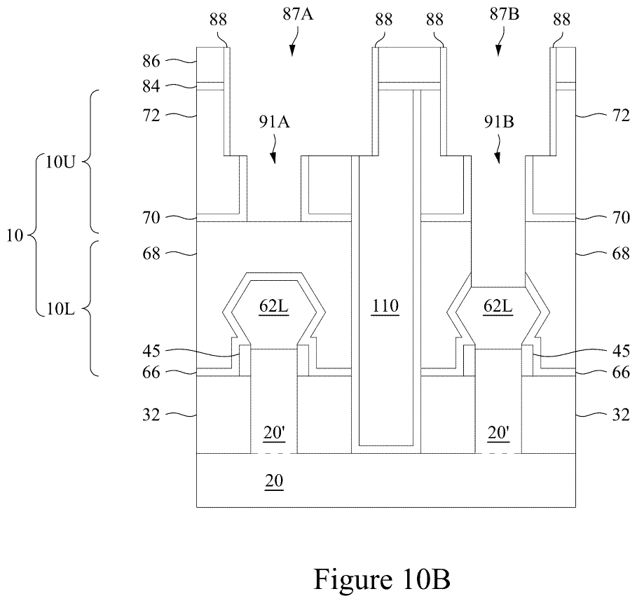

In FIGS. 10A-10B, the mask 93 is removed, in accordance with some embodiments. The mask 93 may be removed using a suitable technique, such as an etching or ashing technique. Other techniques are possible, such as wet chemical techniques. After removing the mask 93, the lower source/drain region 62L is exposed by the opening 91B.

In FIGS. 11A-11B, silicide regions 94 are formed on exposed surfaces of the upper source/drain regions 92 and the lower source/drain region 62L, in accordance with some embodiments. In some embodiments, the silicide regions 94 may be formed by depositing a metal over the structure. The metal may be deposited using a suitable technique, such as CVD, PVD, or the like. The metal of the silicide regions 94 may comprise titanium, vanadium, zinc, niobium, aluminum, nickel, ruthenium, molybdenum, cobalt, or other suitable metals. In some embodiments, an anneal process is then performed to react the metal with the source/drain regions 92/62L to form the silicide regions 94. In other embodiments, the silicide regions 94 are formed by exposing the structure to a metal-containing precursor. The metal-containing precursor reacts with surfaces of the upper source/drain regions 92 and the lower source/drain region 62L to form the silicide regions 94. In some embodiments, after forming the silicide regions 94, an etching or cleaning process may be performed to remove unreacted portions of the metal layer and/or to remove metal-containing residue. In some cases, the silicidation process consumes the exposed portions of upper source/drain regions 92 and/or the lower source/drain region 62L.

In some cases, an electrical conductivity of the silicide regions 94 are greater than an electrical conductivity of the upper source/drain regions 92 or the lower source/drain region 62L. In some cases, forming highly-doped upper source/drain regions 92 as described herein can allow for improved conductivity of the interface between the silicide regions 94 and the upper source/drain regions 92. Increasing conductivity in this manner can increase current flow during operation of the upper nanostructure-FET 10U, which can improve device performance.

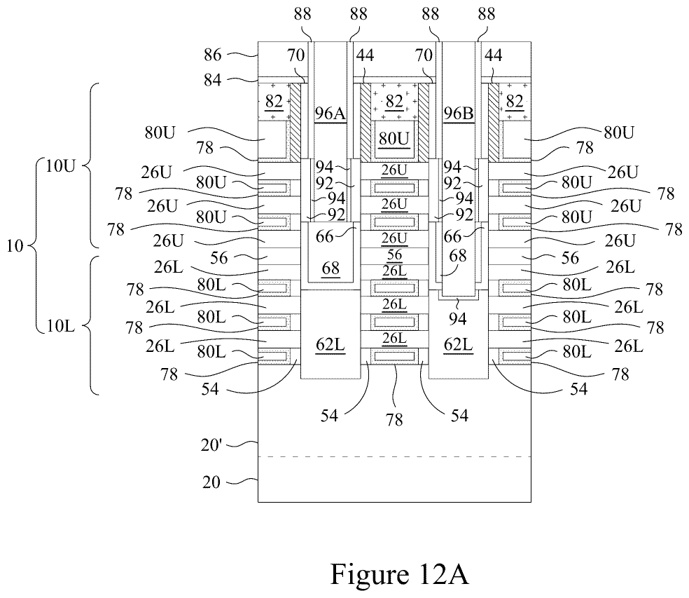

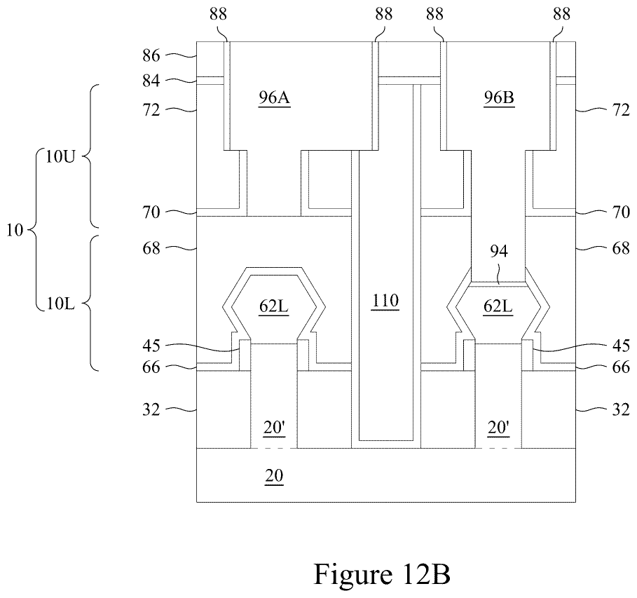

In FIGS. 12A-12B, contact plugs 96A-B are formed on the silicide regions 94, in accordance with some embodiments. The contact plugs 96A-B may be formed by depositing a conductive material that fills the openings 87A-B and the openings 91A-B. The conductive material contacts the silicide regions 94 on the upper source/drain regions 92 and the lower source/drain region 62L. In this manner, the contact plug 96A makes electrical connection to upper source/drain regions 92, and the contact plug 96B makes electrical connection to upper source/drain regions 92 and to a lower source/drain region 62L. Accordingly, the contact plugs 96A-B may be considered source/drain contacts, in some cases. In accordance with some embodiments, the conductive material of the contact plugs 96A-B comprises a metal such as tungsten, cobalt, copper, nickel, molybdenum, ruthenium, iridium, the like, alloys thereof, or combinations thereof. The conductive material may be deposited using a suitable technique, such as CVD, PVD, ALD, or the like. The conductive material may be deposited using a conformal deposition process, in some cases. After depositing the conductive material, a planarization process (e.g., a chemical mechanical polishing (CMP) or grinding process) may be performed to remove excess conductive material. As shown in FIG. 12B, the contact plugs 96A-B may have narrower lower portions, corresponding to the portions filling the openings 91A-B, and wider upper portions, corresponding to the portions filling the openings 87A-B. In some cases, an electrical conductivity of the silicide regions 94 are less than an electrical conductivity of the contact plugs 96A-B.

FIGS. 13A-14B illustrate intermediate stages in the formation of a stacking transistor structure, in accordance with some embodiments. The stacking transistor structure of FIGS. 13A-14B is similar to that shown in FIGS. 1-12B, except that the upper source/drain regions 92 are deposited with a smaller thickness. The materials and processes used to form the embodiment of FIGS. 13A-14B are similar to those used to form the embodiment of FIGS. 1-12B, and accordingly some details are not repeated.

FIGS. 13A-13B illustrate the structure after the upper source/drain regions 92 have been formed, similar to the structure shown in FIGS. 10A-10B. The structure of FIGS. 13A-13B may be formed similarly to the structure shown in FIGS. 10A-10B. For example, after forming replacement gate stacks, the upper dummy regions 62U may be removed, and then upper source/drain regions 92 may be formed on sidewalls of the upper semiconductor nanostructures 26U. The upper source/drain regions 92 may be highly doped. As shown in FIG. 13A, a thickness of the upper source/drain regions 92 is less than a combined thickness of the second CESL 70 and a dielectric liner 88. In some cases, a thickness of the upper source/drain regions 92 may be less than a combined thickness of the first ILD 68 and the first CESL 66. Thus, sidewalls of the openings 91A-B are recessed at the upper source/drain regions 92, and the openings 91A-B have a relatively larger width at the upper source/drain regions 92.

In FIGS. 14A-14B, contact plugs 96A-B are formed, in accordance with some embodiments. The contact plugs 96A-B may be formed similarly to the process shown in FIGS. 11A-12B. For example, silicide regions 94 may be formed on the upper source/drain regions 92 and the lower source/drain region 62L, and then a conductive material may be deposited in the openings 87A-B and the openings 91A-B. As shown in FIGS. 14A-14B, the wider regions of the openings 91A-B due to the thinner upper source/drain regions 92 may allow for the formation of voids or seams in the conductive material near the upper source drain regions 92. The voids or seams are represented in FIGS. 14A-14B by voids 95. In some cases, a void or seam is not formed in the conductive material. The chance of void or seam may be increased if the conductive material is deposited using a conformal process, in some cases. In some cases, forming thinner upper source/drain regions 92 may allow for wider contact plugs 96A-B, which can improve conduction.

FIGS. 15A-16B illustrate intermediate stages in the formation of a stacking transistor structure, in accordance with some embodiments. The stacking transistor structure of FIGS. 15A-16B is similar to that shown in FIGS. 1-12B, except that the upper source/drain regions 92 are deposited with a larger thickness. The materials and processes used to form the embodiment of FIGS. 15A-16B are similar to those used to form the embodiment of FIGS. 1-12B, and accordingly some details are not repeated.

FIGS. 15A-15B illustrate the structure after the upper source/drain regions 92 have been formed, similar to the structure shown in FIGS. 10A-10B. The structure of FIGS. 15A-15B may be formed similarly to the structure shown in FIGS. 10A-10B. For example, after forming replacement gate stacks, the upper dummy regions 62U may be removed, and then upper source/drain regions 92 may be formed on sidewalls of the upper semiconductor nanostructures 26U. The upper source/drain regions 92 may be highly doped. As shown in FIG. 15A, a thickness of the upper source/drain regions 92 is greater than a combined thickness of the second CESL 70 and a dielectric liner 88. In some cases, a thickness of the upper source/drain regions 92 may be greater than a combined thickness of the first ILD 68 and the first CESL 66. Thus, the upper source/drain regions 92 protrude into the openings 91A-B, and the openings 91A-B have a relatively smaller width at the upper source/drain regions 92.

In FIGS. 16A-16B, contact plugs 96A-B are formed, in accordance with some embodiments. The contact plugs 96A-B may be formed similarly to the process shown in FIGS. 11A-12B. For example, silicide regions 94 may be formed on the upper source/drain regions 92 and the lower source/drain region 62L, and then a conductive material may be deposited in the openings 87A-B and the openings 91A-B. As shown in FIGS. 16A-16B, the silicide regions 94 may be formed on top surfaces and/or bottom surfaces of the upper source/drain regions 92. In some cases, the narrower regions of the openings 91A-B due to the thicker upper source/drain regions 92 may allow for the formation of voids or seams in the conductive material near the lower source/drain region 62L. The voids or seams are represented in FIGS. 16A-16B by voids 95. In some cases, a void or seam is not formed in the conductive material. The chance of void or seam may be increased if the conductive material is deposited using a conformal process, in some cases. In some cases, forming thicker upper source/drain regions 92 may allow for silicide regions 94 having greater contact area, which can improve conductivity between the contact plugs 96A-B and the upper source/drain regions 92.

The embodiments of the present disclosure have some advantageous features. By forming dummy upper source/drain regions before the replacement gate stacks, the dummy upper source/drain regions may be replaced after forming the replacement gate stacks. In other words, the upper source/drain regions may be formed using a middle end of line (MEOL) process stage. Since the replacement upper source/drain regions are formed after the replacement gate stacks, the replacement upper source/drain regions are not exposed to high temperatures that may be used during formation of the replacement gate stacks. This can reduce or prevent thermal diffusion between the upper source/drain regions and the upper channel regions (e.g., nanostructures) of the stacked transistor. In this manner, because the replacement upper source/drain regions are formed after the replacement gate stacks, the replacement upper source/drain regions may be formed having a higher doping concentration without increasing unwanted dopant diffusion into the upper channel regions. Forming more highly-doped upper source/drain regions can allow for more conductive (e.g., less resistive) interfaces between the upper source/drain regions and silicide regions formed thereon. Accordingly, the techniques described herein allow for reduced resistance between contacts and upper source/drain regions, which can improve electrical connection and improve device performance.

In accordance with some embodiments of the present disclosure, a method includes forming a lower source/drain region adjacent first channel regions; forming an insulating layer over the lower source/drain region; forming a dummy source/drain region over the insulating layer, wherein the dummy source/drain region is adjacent second channel regions, wherein the second channel regions are over the first channel regions; after forming the dummy source/drain region, forming a gate structure over the first channel regions and the second channel regions; after forming the gate structure, removing the dummy source/drain region; forming an upper source/drain region adjacent the second channel regions; forming a silicide on the upper source/drain region; and forming a contact plug on the silicide, wherein an electrical conductivity of the silicide is between an electrical conductivity of the upper source/drain region and an electrical conductivity of the contact plug. In an embodiment, the silicide is also formed on the lower source/drain region, and wherein the contact plug directly contacts the silicide on the lower source/drain region. In an embodiment, the upper source/drain region is phosphorus-doped silicon. In an embodiment, the upper source/drain region has a doping concentration greater than 1E21 cm⁻³. In an embodiment, removing the dummy source/drain region includes etching an opening that extends through the dummy source/drain region and extends through the insulating layer. In an embodiment, the upper source/drain region extends continuously over the sidewalls of two or more second channel regions. In an embodiment, the upper source/drain region is free of arsenic. In an embodiment, removing the dummy source/drain region includes performing an etching process that selectively etches the dummy source/drain region at a faster rate than the lower source/drain region.

In accordance with some embodiments of the present disclosure, a method includes forming a lower transistor including a first source/drain region and a first gate structure; forming a first inter-layer dielectric over the lower transistor; forming an upper transistor including a second source/drain region and a second gate structure; forming a second inter-layer dielectric over the upper transistor; replacing the second source/drain region with a third source/drain region, including performing a first etching process to expose the second source/drain region; performing a second etching process to remove the second source/drain region; and performing an epitaxial growth process to form the third source/drain region; and forming a first silicide region on the third source/drain region. In an embodiment, the second source/drain region is undoped. In an embodiment, replacing the second source/drain region with a third source/drain region includes performing a third etching process that exposes a sidewall of the second source/drain region and exposes the first source/drain region. In an embodiment, forming the first silicide region also forms a second silicide region on the first source/drain region. In an embodiment, the first source/drain region and the third source/drain region are oppositely doped. In an embodiment, the second source/drain region is silicon germanium. In an embodiment, the method includes forming nanostructures adjacent the first source/drain region and the second source/drain region.

In accordance with some embodiments of the present disclosure, a device includes a lower transistor including a lower source/drain region and first nanostructures; a first silicide region on a top surface of the lower source/drain region; an upper transistor including an upper source/drain region and second nanostructures, wherein the upper source/drain region extends continuously on sidewalls of at least two second nanostructures, wherein the upper source/drain region has a homogeneous composition; a second silicide region covering a sidewall of the upper source/drain region; and a conductive feature on the first silicide region and on the second silicide region. In an embodiment, the upper source/drain region is free of arsenic. In an embodiment, a width of the conductive feature on the second silicide region is greater than a width of the conductive feature on the first silicide region. In an embodiment, the upper source/drain region protrudes into the conductive feature. In an embodiment, a portion of the conductive feature adjacent the second silicide region includes a void.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a lower source/drain region adjacent a plurality of first channel regions;
forming an insulating layer over the lower source/drain region;
forming a dummy source/drain region over the insulating layer, wherein the dummy source/drain region is adjacent a plurality of second channel regions, wherein the plurality of second channel regions is over the plurality of first channel regions;
after forming the dummy source/drain region, forming a gate structure over the plurality of first channel regions and the plurality of second channel regions;
after forming the gate structure, removing the dummy source/drain region;
forming an upper source/drain region adjacent the plurality of second channel regions;
forming a silicide on the upper source/drain region; and
forming a contact plug on the silicide, wherein an electrical conductivity of the silicide is between an electrical conductivity of the upper source/drain region and an electrical conductivity of the contact plug.

2. The method of claim 1, wherein the silicide is also formed on the lower source/drain region, and wherein the contact plug directly contacts the silicide on the lower source/drain region.

3. The method of claim 1, wherein the upper source/drain region is phosphorus-doped silicon.

4. The method of claim 1, wherein the upper source/drain region has a doping concentration greater than 1E21 cm⁻³.

5. The method of claim 1, wherein removing the dummy source/drain region comprises etching an opening that extends through the dummy source/drain region and extends through the insulating layer.

6. The method of claim 1, wherein the upper source/drain region extends continuously over the sidewalls of two or more second channel regions of the plurality of second channel regions.

7. The method of claim 1, wherein the upper source/drain region is free of arsenic.

8. The method of claim 1, wherein removing the dummy source/drain region comprises performing an etching process that selectively etches the dummy source/drain region at a faster rate than the lower source/drain region.

9. A method comprising:
forming a lower transistor comprising a first source/drain region and a first gate structure;
forming a first inter-layer dielectric over the lower transistor;
forming an upper transistor comprising a second source/drain region and a second gate structure;
forming a second inter-layer dielectric over the upper transistor;
replacing the second source/drain region with a third source/drain region, comprising:
performing a first etching process to expose the second source/drain region;
performing a second etching process to remove the second source/drain region; and
performing an epitaxial growth process to form the third source/drain region; and
forming a first silicide region on the third source/drain region.

10. The method of claim 9, wherein the second source/drain region is undoped.

11. The method of claim 9, wherein replacing the second source/drain region with a third source/drain region further comprises performing a third etching process that exposes a sidewall of the second source/drain region and exposes the first source/drain region.

12. The method of claim 9, wherein forming the first silicide region also forms a second silicide region on the first source/drain region.

13. The method of claim 9, wherein the first source/drain region and the third source/drain region are oppositely doped.

14. The method of claim 9, wherein the second source/drain region is silicon germanium.

15. The method of claim 9 further comprising forming a plurality of nanostructures adjacent the first source/drain region and the second source/drain region.

16. A device comprising:
a lower transistor comprising a lower source/drain region and a plurality of first nanostructures;
a first silicide region on a top surface of the lower source/drain region;
an upper transistor comprising an upper source/drain region and a plurality of second nanostructures, wherein the upper source/drain region extends continuously on sidewalls of at least two second nanostructures, wherein the upper source/drain region has a homogeneous composition;
a second silicide region covering a sidewall of the upper source/drain region; and
a conductive feature on the first silicide region and on the second silicide region.

17. The device of claim 16, wherein the upper source/drain region is free of arsenic.

18. The device of claim 16, wherein a width of the conductive feature on the second silicide region is greater than a width of the conductive feature on the first silicide region.

19. The device of claim 16, wherein the upper source/drain region protrudes into the conductive feature.

20. The device of claim 16, wherein a portion of the conductive feature adjacent the second silicide region comprises a void.
